(19) United States
(12) Patent Application Publication
(10) Pub. No.: US 2014/0335684 A1
(43) Pub. Date: Nov. 13, 2014

(54) MANUFACTURING METHOD AND MANUFACTURING APPARATUS OF SEMICONDUCTOR DEVICE

(71) Applicant: KABUSHIKI KAISHA TOSHIBA, Tokyo (JP)

(72) Inventors: Makoto MIZUKAMI, Hyogo (JP); Naoko YANASE, Tokyo (JP); Atsuko YAMASHITA, Hyogo (JP)

(73) Assignee: KABUSHIKI KAISHA TOSHIBA, Tokyo (JP)

(21) Appl. No.: 14/194,358

(22) Filed: Feb. 28, 2014

(30) Foreign Application Priority Data
May 7, 2013 (JP) 2013-097498

(51) Int. Cl. H01L 21/265; H01L 21/67; H01L 21/673; H01L 21/02

(52) U.S. Cl. CPC H01L 21/26513; H01L 21/0262; H01L 21/67; H01L 21/673
USPC 438/522; 118/724; 118/715; 204/298.02; 204/298.15

(57) ABSTRACT

A manufacturing method for a semiconductor device includes implanting dopants into a silicon carbide substrate, applying a carbon-containing material on at least one surface of the silicon carbide substrate, and heating the silicon carbide substrate having the carbon-containing material applied thereon to form a carbon layer on surfaces of the silicon carbide substrate. The heating is performed in a non-oxidizing atmosphere, and is followed by another heating step for activating the dopants.

### CROSS-REFERENCE TO RELATED APPLICATION

This application is based upon and claims the benefit of priority from Japanese Patent Application No. 2013-097498, filed May 7, 2013, the entire contents of which are incorporated herein by reference.

### FIELD

Embodiments described herein relate generally to a manufacturing method and a manufacturing apparatus of a semiconductor device.

### BACKGROUND

If a semiconductor device is to be formed using a silicon carbide (SiC) substrate, annealing for activating dopants is required to be performed after the dopants are ion-implanted into a substrate, in order to adjust a conductivity type of each part of the substrate. A temperature for this annealing is required to be typically about 1600° C. to 2000° C., and SiC is heated to the vicinity of a sublimation temperature since the sublimation temperature of SiC is 2200° C. For this reason, silicon (Si) atoms are desorbed from a surface of the SiC substrate during the annealing, and thus the surface morphology of the SiC substrate deteriorates so as to cause a problem in a semiconductor device.

### DESCRIPTION OF THE DRAWINGS

FIG. 1 is a block diagram illustrating a manufacturing system for a semiconductor device according to a first exemplary embodiment.

FIG. 2 is a cross-sectional view illustrating a carbon layer forming device according to the first exemplary embodiment.

FIG. 3 is a flowchart illustrating a manufacturing method for a semiconductor device according to the first exemplary embodiment.

FIGS. 4A to 4D are cross-sectional views illustrating a manufacturing method for a semiconductor device according to the first exemplary embodiment.

FIGS. 5A to 5D are cross-sectional views illustrating a manufacturing method for a semiconductor device according to a second exemplary embodiment.

FIG. 6 is a cross-sectional view illustrating a carbon layer forming device according to a third exemplary embodiment.

FIG. 7 is a flowchart illustrating a manufacturing method for a semiconductor device according to a fourth exemplary embodiment.

FIG. 8 is a cross-sectional view illustrating a carbon layer forming device according to a fifth exemplary embodiment.

### DETAILED DESCRIPTION

Embodiments provide a manufacturing method and a manufacturing apparatus for a semiconductor device having favorable characteristics.

In general, according to one embodiment, a manufacturing method for a semiconductor device includes implanting dopants into a silicon carbide substrate; applying a carbon-containing material on at least one surface of the silicon carbide substrate; and heating the silicon carbide substrate having the carbon-containing material to form a carbon layer on surfaces of the silicon carbide substrate.

According to another exemplary embodiment, a semiconductor device manufacturing apparatus includes a chamber providing a non-oxidizing atmosphere to a plurality of silicon carbide substrates enclosed therein, the silicon carbide substrates each having dopants implanted therein and at least one surface on which a carbon-containing material has been applied; and a heater configured to heat the chamber and cause a carbon layer to be formed on surfaces of the silicon carbide substrates from carbon atoms in the carbon-containing material.

Hereinafter, with reference to the drawings, exemplary embodiments will be described.

First, a first exemplary embodiment will be described.

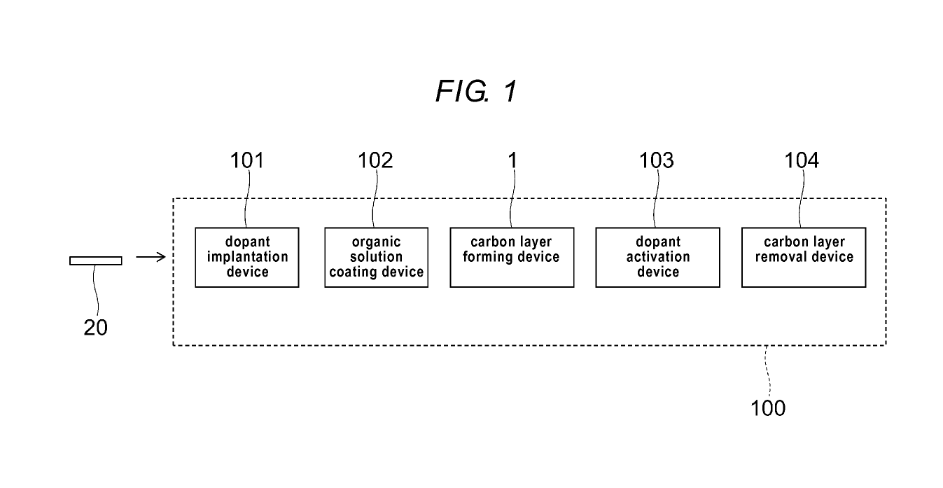

FIG. 1 is a block diagram illustrating a manufacturing system for a semiconductor device according to the present exemplary embodiment.

As shown in FIG. 1, the manufacturing system 100 for a semiconductor device according to the present exemplary embodiment is provided with dopant implantation device 101, an organic solution coating device 102, a carbon layer forming device 1, dopant activation device 103, and a carbon layer removal device 104. An SiC substrate 20 is a semiconductor substrate made of silicon carbide (SiC), and is, for example, a single-crystalline SiC wafer.

The dopant implantation device 101 is a device which ion-implants dopants into a predetermined region of the SiC substrate 20. The dopants adjust a conductivity type of the SiC substrate 20, and is, for example, boron (B), nitrogen (N), aluminum (Al), phosphorous (P), or the like.

The organic solution coating device 102 is a device which coats an organic solution on the surface of the SiC substrate 20, and is, for example, a spin coater.

The carbon layer forming device 1 is a device which heats the SiC substrate 20 in a non-oxidizing atmosphere, for example, in an inert gas atmosphere, so as to vaporize the organic solution coated on the surface of the SiC substrate 20, thereby forming a carbon layer on the surface of the SiC substrate. A configuration and an operation of the carbon layer forming device 1 will be described later.

The dopant activation device 103 is a device which heats the SiC substrate 20, for example, to a temperature of 1600° C. to 2000° C. so as to activate the dopants implanted into the SiC substrate 20 by the dopant implantation device 101.

The carbon layer removal device 104 is a device which heats the SiC substrate 20 in an oxygen atmosphere, for example, to a temperature of 400° C. to 1000° C., so as to remove the carbon layer.

Next, the carbon layer forming device 1 according to the present exemplary embodiment will be described.

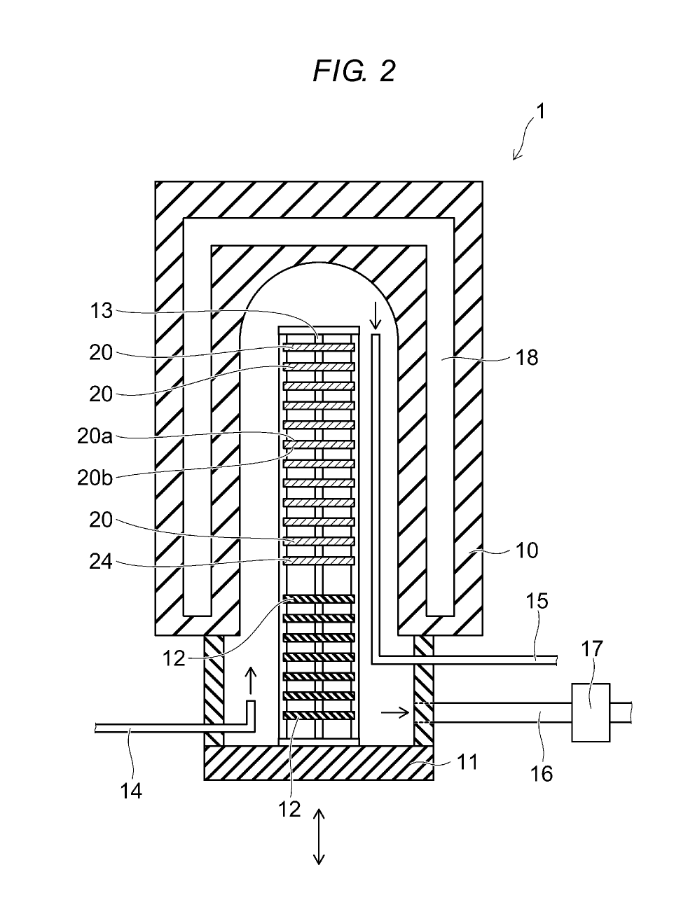

FIG. 2 is a cross-sectional view illustrating the carbon layer forming device according to the present exemplary embodiment.

As shown in FIG. 2, a chamber 10 made of a heat-resistant material is provided in the carbon layer forming device 1. A lower end of the chamber 10 is open.

A disc-shaped lifting plate 11 is provided on the lower side of the chamber 10. The lifting plate 11 is connected to a boat elevator (not shown) and can move vertically. When the lifting plate 11 is located at an upper end of a movement range thereof, the chamber 10 is sealed, and when the lifting plate 11 is located at a lower end of the movement range, the chamber 10 is opened so that the SiC substrate 20 can be attached onto and detached from the lifting plate 11. As described later, the SiC substrate 20 into which, for example, dopants are implanted and in which an organic solution is coated on one surface, is placed into the chamber 10.

A boat or cassette 13 is provided on the lifting plate 11. In the boat 13, three or four posts are provided so as to be parallel to each other, for example, between disc-shaped bottom plate and top plate. Dents (not shown) are formed on a side surface of each post, and end parts of the SiC substrate 20 are hung on the dents, thereby holding the SiC substrate 20. A plurality of heat shield plates 12 are inserted into the lower part of the boat 13 and are thus held by the boat 13. The heat shield plates 12 thermally shield the inside and outside of the chamber 10. A plurality of SiC substrates 20 are inserted into the upper part of the boat 13 and are thus held by the boat 13. The boat 13 can hold a plurality of SiC substrates 20 so as to be spaced apart from each other and be parallel to each other. The boat 13 holds the SiC substrate 20 so that the surface thereof is horizontal.

In addition, a feed pipe 14 for introducing an inert gas into the chamber 10 and an exhaust pipe 15 for discharging a gas in the chamber 10 are installed in the chamber 10. Accordingly, the inside of the chamber 10 can be set to a non-oxidizing atmosphere, specifically, an inert gas atmosphere. Further, one end of a vacuum-drawing line 16 is connected to the chamber 10, and the other end of the vacuum-drawing line 16 is connected to a pump 17. Air in the chamber 10 can be discharged by the pump 17 and the vacuum-drawing line 16 such that the chamber 10 becomes a vacuum.

Furthermore, a heater 18 is provided inside of a wall member forming the upper part and central part of the chamber 10. The heater 18 heats the SiC substrate 20 placed into the chamber 10, for example, to a temperature of 200° C. to 1000° C.

Next, a description will be made of an operation of the manufacturing system for a semiconductor device configured in this way, that is, a manufacturing method for a semiconductor device according to the present exemplary embodiment.

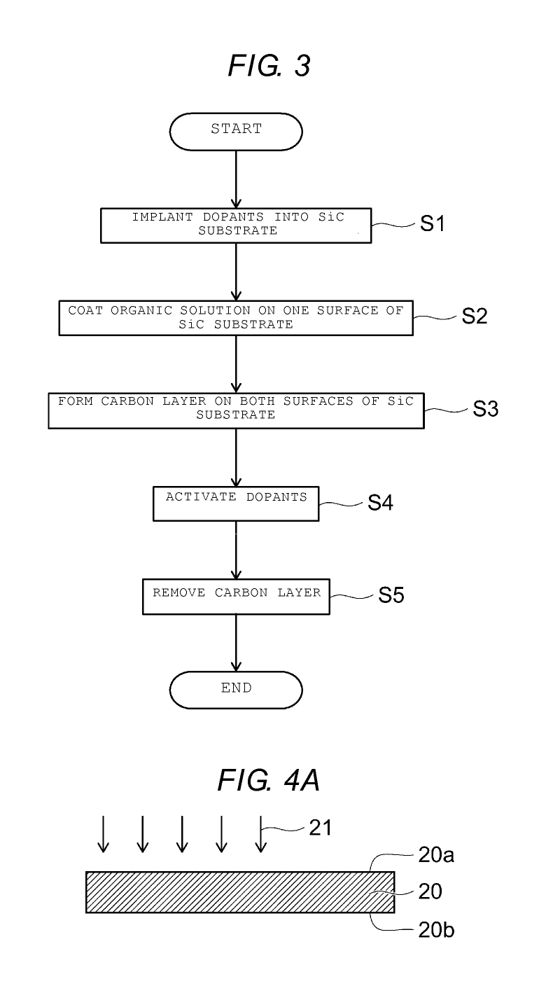

FIG. 3 is a flowchart illustrating a manufacturing method of a semiconductor device according to the present exemplary embodiment.

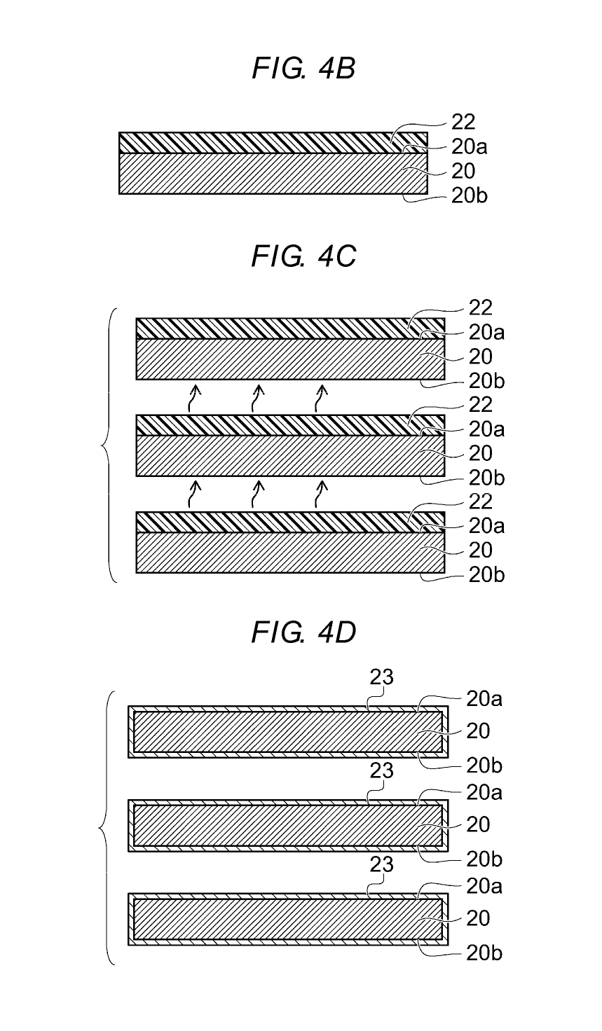

FIGS. 4A to 4D are cross-sectional views illustrating a manufacturing method of a semiconductor device according to the present exemplary embodiment.

First, as shown in step S1 of FIG. 3 and FIG. 4A, the SiC substrate 20 made of silicon carbide (SiC) is prepared. Next, the dopant implantation device 101 ion-implants dopants 21 into a predetermined region of the SiC substrate 20. As described above, the dopants 21 are, for example, boron (B), nitrogen (N), aluminum (Al), phosphorous (P), or the like.

Next, as shown in step S2 of FIG. 3 and FIG. 4B, the organic solution coating device 102 coats an organic solution on a front surface 20a of the SiC substrate 20 so as to form an organic solution layer 22 on the front surface 20a. The organic solution is a solution in which, for example, solutes with a carbon skeleton are dissolved in an organic solvent, and is, for example, a photoresist. The solutes with a carbon skeleton are, for example, a novolac resin. In addition, a coating method is, for example, a spin coating method. Further, the organic solution is not coated and thus the organic solution layer 22 is not formed, on a rear surface 20b of the SiC substrate 20.

Next, as shown in FIG. 2, step S3 of FIG. 3, and FIG. 4C, a plurality of SiC substrates 20 provided with the organic solution layer 22 on the front surface 20a are loaded onto the boat 13 in a state in which the lifting plate 11 of the carbon layer forming device 1 is lowered. At this time, the plurality of SiC substrates 20 are parallel to each other with a predetermined gap, and are arranged in the same direction as each other. Accordingly, in each SiC substrate 20, the rear surface 20b on which the organic solution layer 22 is not formed faces the organic solution layer 22 formed on the front surface 20a of the adjacent SiC substrate 20. In addition, in FIG. 2, the organic solution layer 22 is not shown. Further, a substrate 24 of which the organic solution layer 22 is formed on a surface may be disposed so as to face the rear surface 20b of the SiC substrate 20 arranged at the outermost end.

Successively, the lifting plate 11 is moved up. Therefore, the lifting plate 11 contacts with the lower end of the chamber 10 such that the SiC substrates 20 are placed into the chamber 10 and the chamber 10 is also in an airtight state.

Next, the pump 17 is operated so as to make the inside of the chamber 10 a vacuum via the vacuum-drawing line 16, and then the pump 17 stops being operated. Subsequently, an inert gas is supplied to the inside of the chamber 10 via the feed pipe 14, and a gas in the chamber 10 is discharged via the exhaust pipe 15. Therefore, the gas in the chamber 10 is replaced with the inert gas. As a result, the inside of the chamber 10 is in an inert gas atmosphere. In addition, an atmosphere in the chamber 10 is not limited to the inert gas atmosphere, and may be any non-oxidizing atmosphere.

Next, the heater 18 is operated so as to heat the SiC substrates 20 via the atmospheric gas in the chamber 10. A heating temperature is, for example, 200° C. to 1000° C. Accordingly, the organic solvent is vaporized from the organic solution layer 22 formed on the front surface 20a of the SiC substrate 20, and, simultaneously, some of the solutes are vaporized such that the vaporized solutes are attached to the rear surface 20b of the adjacent opposed SiC substrate 20 via the gap. Next, the solutes attached to the SiC substrate 20, that is, the organic substances undergo a dehydration condensation reaction due to the heating, thereby forming a dense carbon layer 23. A temperature at this time is, for example, 200° C. to 500° C. Here, the term “dense” indicates a state in which an opening is not substantially formed, and the carbon layer is interposed as a continuous layer between the SiC substrate 20 and the atmosphere. The dense carbon layer 23 may be, for example, a layer that is entirely graphitized so as to form a hexagonal plate crystal with consecutive sp2 hybrid orbitals, but is not limited thereto, and may be a layer that is partially graphitized and a remaining part has another form, or a layer that has forms other than graphite, such as diamond.

As a result, as shown in FIG. 4D, the carbon layer 23 is formed on all the surfaces of the SiC substrate 20. In other words, the carbon layer 23 is formed on the front surface 20a, the rear surface 20b and the end surfaces of the SiC substrate 20. In addition, the vaporized solutes which do not contribute to the formation of the carbon layer 23 and the vaporized organic solvent are discharged to the outside of the chamber 10 via the exhaust pipe 15. Successively, an output of the heater 18 is reduced so as to cool the SiC substrate 20 and the carbon layer 23 to an extraction temperature, then the lifting plate 11 is moved down, and the chamber 10 is opened so as to extract the SiC substrate 20 from the chamber 10.

Next, as shown in step S4 of FIG. 3, the SiC substrate 20 is placed into the dopant activation device 103, and is heated, for example, to a temperature of 1600° C. to 2000° C. in an inert gas atmosphere. Accordingly, the dopants 21 introduced into the SiC substrate 20 is activated. In this case, since the surfaces of the SiC substrate 20 are coated with the carbon layer 23, silicon atoms forming the SiC substrate 20 can be suppressed from being desorbed due to the heating.

Next, as shown in step S5 of FIG. 3, the SiC substrate 20 is placed into the carbon layer removal device 104, and is heated, for example, to 400° C. to 1000° C. in an oxygen atmosphere. Accordingly, the carbon layer 23 is oxidized and is thus removed. Thereafter, normal steps are performed so as to manufacture a semiconductor device.

Next, effects of the present exemplary embodiment will be described.

In the present exemplary embodiment, all the surfaces of the SiC substrate 20 are coated with the carbon layer 23 before the dopants are activated by heating the SiC substrate 20. For this reason, when the annealing shown in step S4 of FIG. 3 is performed, silicon atoms can be suppressed from being desorbed from the surfaces of the SiC substrate 20, thereby preventing a deterioration in the surface morphology of the SiC substrate 20 and a deterioration in characteristics of a manufactured semiconductor device, for example, forward characteristics and reverse characteristics.

In addition, in the present exemplary embodiment, since the organic solution layer 22 is formed on the front surface 20a of the SiC substrate 20 by a coating method, the organic solution layer 22 can be formed simply at a low cost in a safe method. Further, in the present exemplary embodiment, a plurality of SiC substrates 20 are disposed so as to be parallel to each other and be spaced apart from each other, and solutes are vaporized from the organic solution layer 22 formed on the front surface 20a of a certain SiC substrate 20 so as to be attached to the rear surface 20b of an adjacent SiC substrate 20. For this reason, an organic solution is preferably coated only on the front surface 20a of the SiC substrate 20 and thus productivity is high.

In contrast, if all the surfaces of the SiC substrate 20 are to be coated with an organic solution only using the coating method, the front surface 20a and the rear surface 20b cannot be processed at the same time, and thus at least two coating steps would be required, thereby decreasing productivity. In addition, if a carbon layer is to be formed by methods other than the coating method, for example, a chemical vapor deposition (CVD) method or a sputtering method, there would be an increase in cost. In the present exemplary embodiment, since the carbon layer 23 can be formed on all the surfaces of the SiC substrate 20 in a single step of coating and heating, processing cost is low.

Next, a second exemplary embodiment will be described.

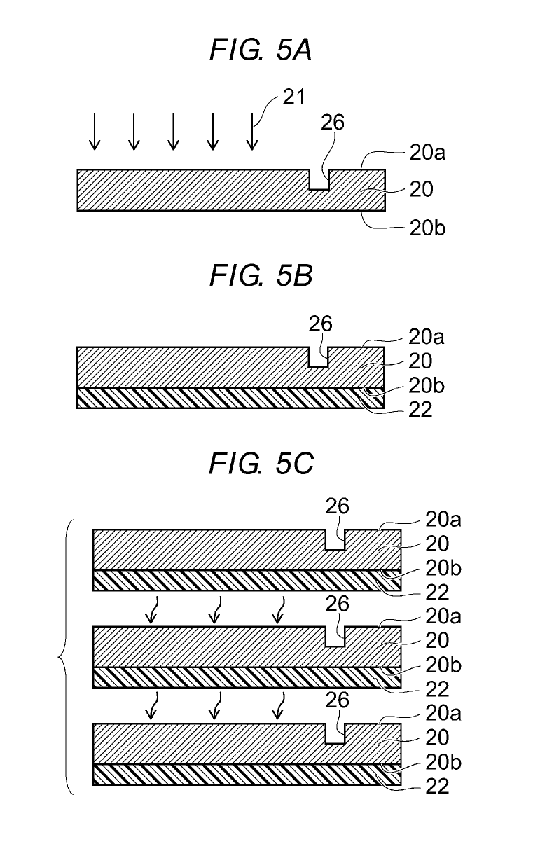

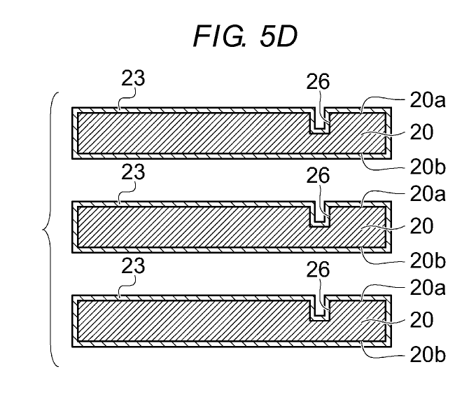

FIGS. 5A to 5D are cross-sectional views illustrating a manufacturing method of a semiconductor device according to the present exemplary embodiment.

In the present exemplary embodiment, as shown in FIG. 5A, before the step of coating an organic solution, shown in step S2 of FIG. 3, for example, and before the step of implanting dopants, shown in step S1, a trench 26 is formed in the front surface 20a of the SiC substrate 20.

Next, as shown in step S2 of FIG. 3 and FIG. 5B, an organic solution is coated not on the front surface 20a of the SiC substrate 20 but on the rear surface 20b thereof, so as to form an organic solution layer 22 on the rear surface 20b.

Accordingly, as shown in FIG. 5C, in the step of forming a carbon layer, shown in step S3 of FIG. 3, solutes are vaporized from the organic solution layer 22 formed on the rear surface 20b of each SiC substrate 20, and the vaporized solutes are attached to the front surface 20a of the SiC substrate 20 which is disposed around the rear surface 20b side. As a result, as shown in FIG. 5D, the carbon layer 23 is formed on all the surfaces of the SiC substrate 20 including the inside of the trench 26. The subsequent steps are the same as in the above-described first exemplary embodiment.

Next, effects of the present exemplary embodiment will be described.

If an organic solution is coated on the front surface 20a in which the trench 26 is formed in the SiC substrate 20, bubbles remain when the organic solution enters the trench 26, and thus there is a probability that a coating ratio may decrease.

Therefore, in the present exemplary embodiment, the organic solution is coated not on the front surface 20a in which the trench 26 is formed but on the rear surface 20b. Accordingly, vaporized solutes become airborne and are attached to the front surface 20a such that the carbon layer 23 is formed through a dehydration condensation reaction. As a result, the carbon layer 23 can also be reliably and uniformly formed on the inside of the trench 26.

Devices, a manufacturing method, and effects of the present exemplary embodiment other than the above description are the same as in the above-described first exemplary embodiment.

Next, a third exemplary embodiment will be described.

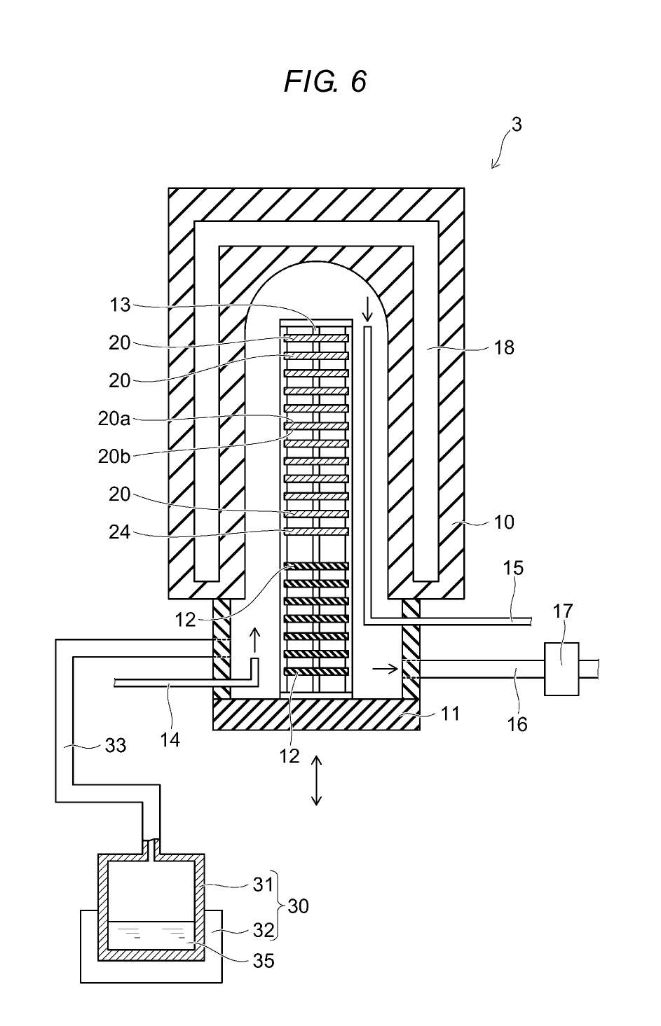

FIG. 6 is a cross-sectional view illustrating a carbon layer forming device according to the present exemplary embodiment.

As shown in FIG. 6, a solute supply unit 30 is provided in the carbon layer forming device 3 according to the present exemplary embodiment, in addition to the configuration of the carbon layer forming device 1 (refer to FIG. 2) according to the above-described first exemplary embodiment.

A container 31 that holds a liquid organic solution 35 and a heater 32 that heats the organic solution 35 held in the container 31 are provided in the solute supply unit 30. The inside of the container 31 communicates with the inside of the chamber 10 via a vapor pipe 33. In addition, the heater 32 heats the organic solution 35 in the container 31 so as to generate vapor of the organic solution 35. The vapor of the organic solution 35 includes a vaporized solvent and vaporized solutes contained in the organic solution 35. Further, the vapor is supplied to the inside of the chamber 10 via the vapor pipe 33. However, the solute supply unit 30 is disposed outside the chamber 10 and is thus substantially thermally isolated from the chamber 10.

According to the present exemplary embodiment, in the step of forming a carbon layer, shown in step S3 of FIG. 3, since vaporized solutes are supplied to the SiC substrate 20 not only from the organic solution layer 22 formed on the front surface 20a of the adjacent SiC substrate 20 but also from the solute supply unit 30, the carbon layer 23 can be prevented from being insufficiently formed due to lack of material, thereby reliably covering the SiC substrate 20 with the carbon layer 23. In addition, solutes of the organic solution 35 are vaporized not in the chamber 10 but in the solute supply unit 30 which is substantially thermally isolated from the chamber 10, the organic solution 35 is not overheated or solidified due to heat of the heater 18.

Device configurations, a manufacturing method, and effects of the present exemplary embodiment other than the above description are the same as in the above-described first exemplary embodiment. In addition, an ultrasound generation device may be provided in the solute supply unit 30 instead of the heater 32. Further, the present exemplary embodiment may be combined with the above-described second exemplary embodiment.

Next, a fourth exemplary embodiment will be described.

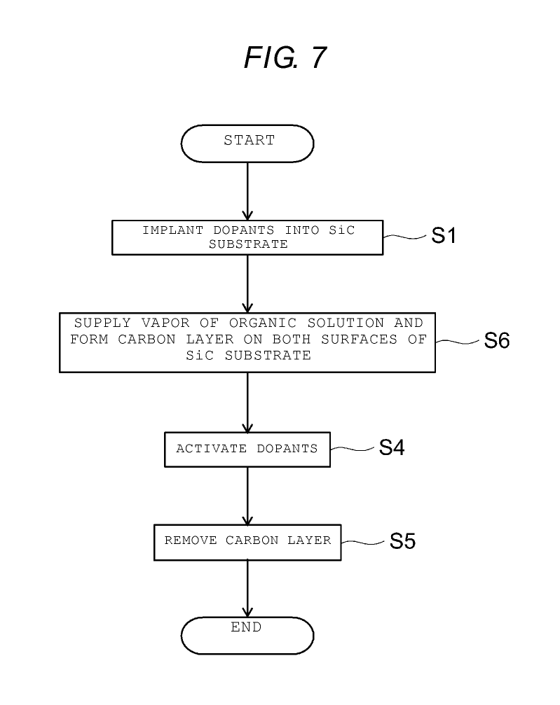

FIG. 7 is a flowchart illustrating a manufacturing method of a semiconductor device according to the present exemplary embodiment.

As shown in FIG. 7, in comparison with the present exemplary embodiment with the manufacturing method (refer to FIG. 3) according to the above-described first exemplary embodiment, there is a difference in that the step of coating an organic solution, shown in step S2 of FIG. 3, and the step of forming a carbon layer, shown in step S3 thereof, are integrated into a single step shown in step S6 of FIG. 7.

In other words, in the present exemplary embodiment, as shown in step S1 of FIG. 7, after dopants are implanted into the SiC substrate 20, an organic solution is not coated, and as shown in step S6, the SiC substrate 20 is placed into the carbon layer forming device 3 shown in FIG. 6. In addition, vaporized solutes of the organic solution 35 are introduced into the chamber 10 by the solute supply unit 30, and the carbon layer 23 is formed on all the surfaces of the SiC substrate 20 by the heater 18 performing a heating process. The subsequent steps are the same as in the above-described first exemplary embodiment.

According to the present exemplary embodiment, since vapor of the organic solution 35 is supplied to the inside of the chamber 10 by the solute supply unit 30, the organic solution layer 22 is not required to be formed on the SiC substrate 20 in advance, and thus a step of coating an organic solution can be omitted. Accordingly, a manufacturing cost of a semiconductor device can be further reduced.

Device configurations, a manufacturing method, and effects of the present exemplary embodiment other than the above description are the same as in the above-described third exemplary embodiment. In addition, the present exemplary embodiment may be combined with the above-described second exemplary embodiment.

Next, a fifth exemplary embodiment will be described.

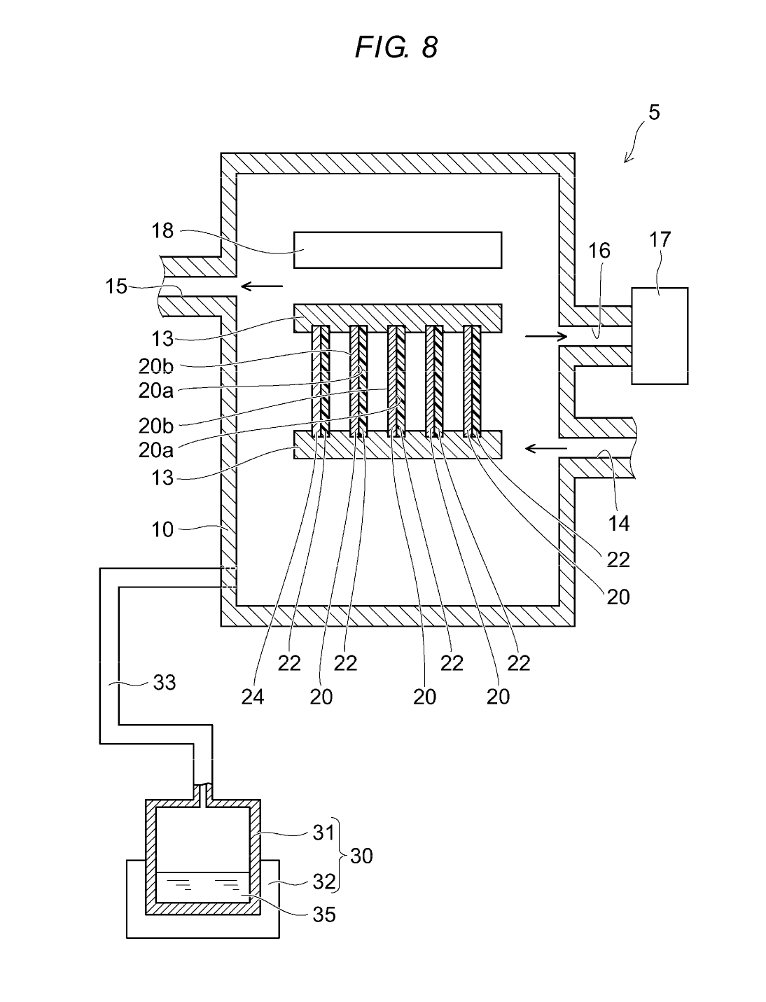

FIG. 8 is a cross-sectional view illustrating a carbon layer forming device according to the present exemplary embodiment.

As shown in FIG. 8, in the carbon layer forming device 5 according to the present exemplary embodiment, a plurality of SiC substrates 20 are held such that surfaces thereof are vertical. In addition, the solute supply unit 30 is provided in the same manner as in the carbon layer forming device 3 (refer to FIG. 6) according to the above-described third exemplary embodiment.

Device configurations, a manufacturing method, and effects of the present exemplary embodiment other than the above description are the same as in the above-described third exemplary embodiment. In addition, in the present exemplary embodiment, in the same manner as in the above-described second exemplary embodiment, the trench 26 may be formed in the front surface 20a of the SiC substrate 20, and the organic solution layer 22 may be formed on the rear surface 20b. Further, in the same manner as in the above-described fourth exemplary embodiment, an organic solution may be coated on neither of the front surface 20a nor the rear surface 20b of the SiC substrate 20, and the carbon layer 23 may be formed only using solutes supplied from the solute supply unit 30.

According to the above-described exemplary embodiments, a manufacturing method and a manufacturing device of a semiconductor device with favorable characteristics can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
implanting dopants into a silicon carbide substrate;
applying a carbon-containing material on at least one surface of the silicon carbide substrate; and
heating the silicon carbide substrate having the carbon-containing material applied thereon to form a carbon layer on surfaces of the silicon carbide substrate.

2. The method according to claim 1, wherein the carbon layer is formed on an upper surface, a lower surface, and side surfaces of the silicon carbide substrate by the heating.

3. The method according to claim 1, wherein the heating is conducted in a non-oxidizing atmosphere.

4. The method according to claim 3, wherein the non-oxidizing atmosphere is an inert gas atmosphere.

5. The method according to claim 1, further comprising:
heating the silicon carbide substrate having the carbon layer formed on the surfaces thereof, to activate the dopants implanted therein.

6. The method according to claim 5, further comprising:
after the dopants implanted in the silicon carbide substrate have been activated, heating the silicon carbide substrate in an oxygen atmosphere to remove the carbon layer.

7. The method according to claim 1, wherein the carbon-containing material is applied by a spin coating method.

8. The method according to claim 1, wherein the carbon-containing material is supplied in gaseous form from an external source and applied onto the surface of the silicon carbide substrate by a dehydration condensation reaction.

9. The method according to claim 1, wherein
a plurality of silicon carbide substrates are arranged so that the planar surfaces thereof are parallel.

10. The method according to claim 9, wherein the carbon-containing material is applied to upper planar surfaces of the silicon carbide substrates.

11. The method according to claim 9, wherein the carbon-containing material is applied to lower planar surfaces of the silicon carbide substrates.

12. A semiconductor device manufacturing apparatus comprising:
a chamber providing a non-oxidizing atmosphere to a plurality of silicon carbide substrates enclosed therein, the silicon carbide substrates each having dopants implanted therein and at least one surface on which a carbon-containing material has been applied; and
a heater configured to heat the chamber and cause a carbon layer to be formed on surfaces of the silicon carbide substrates from carbon atoms in the carbon-containing material.

13. The apparatus according to claim 12, further comprising:
a cassette that is provided in the chamber, and holds the plurality of silicon carbide substrates so that planar surfaces thereof are parallel.

14. The apparatus according to claim 13, wherein the planar surfaces are arranged horizontally.

15. The apparatus according to claim 13, wherein the planar surfaces are arranged vertically.

16. The apparatus according to claim 12, further comprising:
a solute supply unit configured to vaporize solutes of an organic solution outside of the chamber and supply the vaporized solutes into the chamber.

17. The apparatus according to claim 12, wherein the non-oxidizing atmosphere is an inert gas atmosphere.

18. A semiconductor device manufacturing apparatus, comprising:
a chamber providing a non-oxidizing atmosphere to a plurality of silicon carbide substrates enclosed therein, the silicon carbide substrates each having dopants implanted therein; and
a solute supply unit configured to vaporize solutes of an organic solution outside of the chamber and supply the vaporized solutes into the chamber.

19. The apparatus according to claim 17, further comprising:
a cassette that is provided in the chamber, and holds the plurality of silicon carbide substrates so that planar surfaces thereof are parallel.

20. The apparatus according to claim 19, wherein the planar surfaces are arranged either horizontally or vertically.
